(19) United States
(12) Patent Application Publication
(10) Pub. No.: US 2014/0014163 A1
(43) Pub. Date: Jan. 16, 2014

(54) CLIP FASTENER FOR GROUNDING PHOTOVOLTAIC SYSTEM

(71) Applicants: William E. McCarthy, Edwardsville, IL (US); Travis Shelton, Edwardsville, IL (US); Brandon M. Tally, Greenville, IL (US); Eric R. Nuernberger, Highland, IL (US)

(72) Inventors: William E. McCarthy, Edwardsville, IL (US); Travis Shelton, Edwardsville, IL (US); Brandon M. Tally, Greenville, IL (US); Eric R. Nuernberger, Highland, IL (US)

(73) Assignee: COOPER TECHNOLOGIES COMPANY, Houston, TX (US)

(21) Appl. No.: 13/545,602

(22) Filed: Jul. 10, 2012

(51) Int. Cl. H01R 4/24; H02G 15/02; H01L 31/048

(52) U.S. Cl. 136/251; 174/75 F; 439/426

(57) ABSTRACT

A module clip for use in grounding a photovoltaic module through electrical connection with a racking assembly on which the photovoltaic module is mountable. The module clip includes upper and lower clip jaws at least partially defining a press-fit channel for press fitting the module clip onto a lower flange of the photovoltaic module. A piercing member on at least one of the upper and lower clip jaws pierces an electrically non-conductive outer layer on the lower flange of the photovoltaic module and contacts an electrically conductive material of the lower flange as the module clip is press fit onto the lower flange. A lead-connecting member of the module clip is used in securing a ground wire to the module clip.

### FIELD OF THE DISCLOSURE

The present disclosure generally relates to a clip fastener for use in grounding photovoltaic modules of a photovoltaic system.

### BACKGROUND

A photovoltaic system (or PV system) is a system which uses one or more photovoltaic modules (or solar panels) to convert sunlight into electricity. The system may include multiple components, including the photovoltaic modules, a racking assembly on which the modules are mounted, mechanical and electrical connections, and devices for regulating and/or modifying the electrical output. Most photovoltaic systems include a photovoltaic array, which is a linked collection of photovoltaic modules. In the case of ground-mounted photovoltaic systems, the photovoltaic modules are mounted on a plurality of racking assemblies assembled in vacant land areas. Such ground-mounted photovoltaic systems may include thousands, if not tens of thousands, photovoltaic modules. Accordingly, the time it takes to assemble each racking assembly and mount the photovoltaic modules on of the photovoltaic modules to the racking assemblies may significantly reduce the overall cost of the photovoltaic system.

### SUMMARY

In one aspect, a ground lead assembly for use in grounding a photovoltaic module through electrical connection with a racking assembly on which the photovoltaic module is mountable generally comprises a module clip configured for securement to the photovoltaic module. The module clip includes upper and lower clip jaws at least partially defining a press-fit channel for press fitting the module clip onto a lower flange of the photovoltaic module, and a piercing member on at least one of the upper and lower clip jaws for piercing an electrically non-conductive outer layer on the lower flange of the photovoltaic module and contacting an electrically conductive material of the lower flange as the module clip is press fit onto the lower flange. A rail-attachment component is connected electrically to the module clip. The rail-attachment component is configured for securement to and electrical connection with a rail of the racking system.

In another aspect, a module clip for use in grounding a photovoltaic module through electrical connection with a racking assembly on which the photovoltaic module is mountable generally comprises upper and lower clip jaws at least partially defining a press-fit channel for press fitting the module clip onto a lower flange of the photovoltaic module. A piercing member is on at least one of the upper and lower clip jaws for piercing an electrically non-conductive outer layer on the lower flange of the photovoltaic module and contacting an electrically conductive material of the lower flange as the module clip is press fit onto the lower flange. A lead-connecting member is for use in securing a ground wire to the module clip. The piercing member is electrically connected to the lead-connecting member so as to define an electrical path from the piercing member to the lead-connecting member. The module clip has a current-carrying capacity through said electrical path of at least about 750 amps for 4 seconds.

In yet another aspect, a photovoltaic system generally comprises a racking assembly including a rail. A photovoltaic module is mounted on the rail of the racking assembly. The photovoltaic module includes a frame having a lower flange. The frame is constructed from an electrically-conductive material having an electrically non-conductive outer layer disposed over the electrically conductive material. A ground lead assembly grounds the at least one photovoltaic module through electrical connection with the rail on which the photovoltaic module is mounted. The ground lead assembly includes a module clip press fit on the lower flange of the photovoltaic module. The module clip has a piercing member electrically contacting the electrically conductive material. A rail-attachment component is secured to the rail in electrical connection therewith. The rail-attachment component is electrically connected to the module clip to provide an electrical path from the electrically conductive material of the photovoltaic module through the ground lead assembly to the rail.

Other features will be in part apparent and in part pointed out hereinafter.

### BRIEF DESCRIPTION OF THE DRAWINGS

FIG. 1 is a perspective of one embodiment of a photovoltaic module mounted on a single rail of a racking assembly;

FIG. 2 is an enlarged, partial view of FIG. 1, as indicated in FIG. 1, showing a ground lead assembly electrically connecting the photovoltaic module to the rail;

FIG. 3 is an enlarged, exploded view of the ground lead assembly;

FIG. 4 is an enlarged perspective of the ground lead assembly showing a clip fastener of the ground lead assembly secured to the photovoltaic module;

FIG. 5 is an enlarged, partial cross section taken through the photovoltaic module and the clip fastener secured to the photovoltaic module;

FIG. 6 is an enlarged front perspective of the clip fastener;

FIG. 7 is a rear perspective of the clip fastener in FIG. 6;

FIG. 8 is a rear elevational view of the clip fastener in FIG. 6; and

FIG. 9 is a side elevational view of the clip fastener in FIG. 6.

Corresponding reference characters indicate corresponding parts throughout the drawings.

### DETAILED DESCRIPTION OF THE DRAWINGS

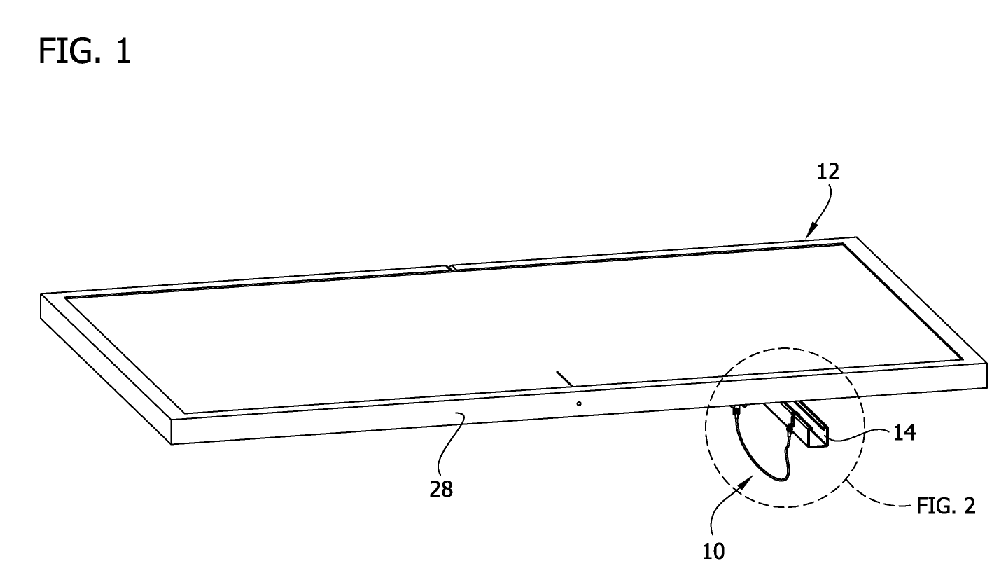

Referring now to the drawings, and in particular to FIGS. 1-4, one embodiment of a ground lead assembly is generally indicated at reference numeral 10. The ground lead assembly 10 is configured for use in grounding a photovoltaic module, generally indicated at 12 (also referred to herein as “module”), of a photovoltaic system to a racking assembly of the system. Although only one photovoltaic module 12 is illustrated in the drawings, the photovoltaic system may—and typically will—include a plurality of photovoltaic modules 12, mounted on the racking assembly, and therefore, a plurality of ground lead assemblies 10 will be employed in a single photovoltaic system. The racking assembly may be configured for ground mounting of the photovoltaic modules 12 or for mounting the photovoltaic modules on a roof of a building or other structure. In the drawings, only a single rail 14 of the racking assembly is illustrated, with the understanding that the racking assembly may include one or more piers (not shown) that extend upward from the ground or a roof, and additional rails (not shown) secured to the piers. The illustrated rail 14 is a channel-type rail, and channel-type fasteners (e.g., hold down clamps, not shown) may be used to secure the modules 12 to the rail, although the modules may be secured to the rails in other ways and other types of rails may be used in place of the illustrated channel-type rail. As a non-limiting example, a suitable ground racking assembly is the Ground Mount Solar Racking System, available from Cooper B-Line of Highland, Ill., and a suitable rooftop racking assembly is the ARISTA™ Monolithic Commercial Rooftop Racking System, available from Cooper B-Line of Highland, Ill. The ground lead assembly 10 disclosed herein may be used with other types of racking assemblies of a photovoltaic system.

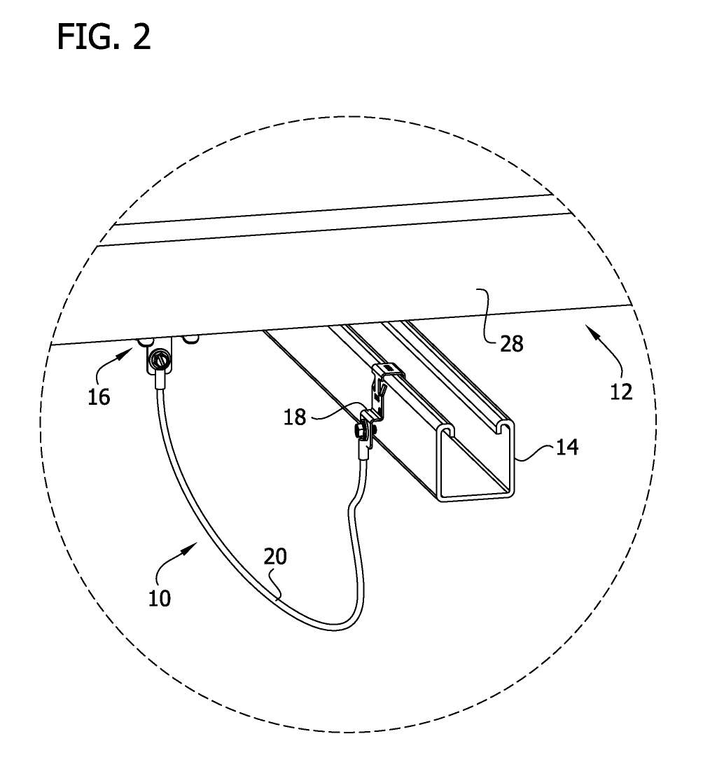

Referring to FIGS. 2-4, the ground lead assembly 10 includes a module clip, generally indicated at 16, a rail-attachment component 18 (e.g., a strut-channel clip), and a ground wire 20 (e.g., a cable or wire) secured to and electrically connecting the module clip to the rail-attachment component. As explained in more detail below, the module clip 16 is securable to photovoltaic module 12 for establishing an electrical connection therewith, and the rail-attachment component 18 is securable to the rail 14 of the racking assembly for establishing an electrical connection therewith.

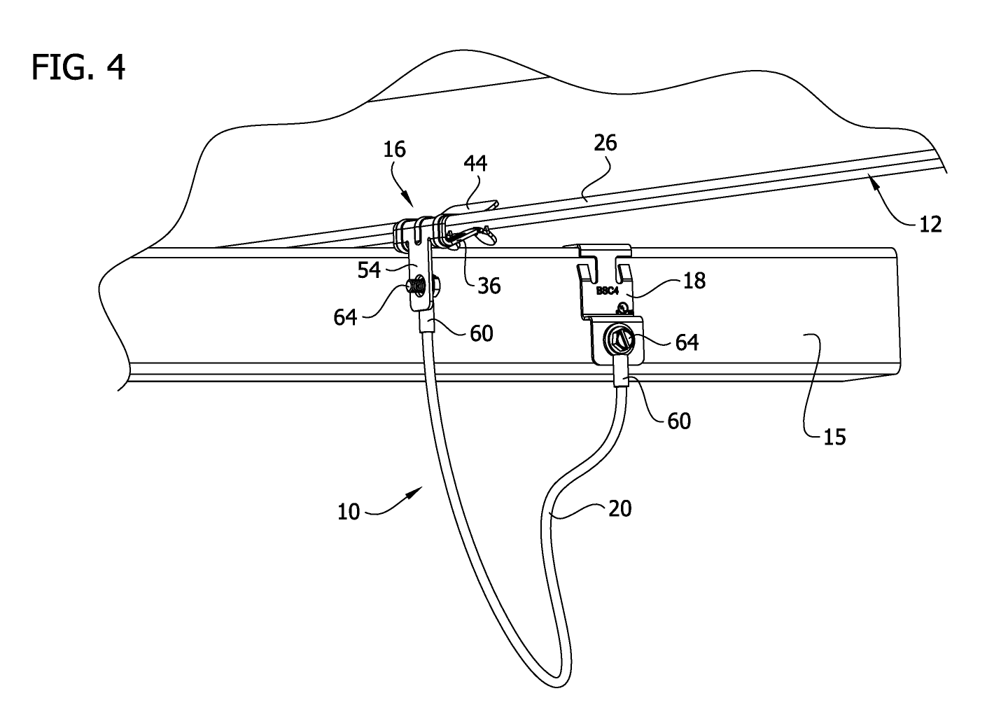

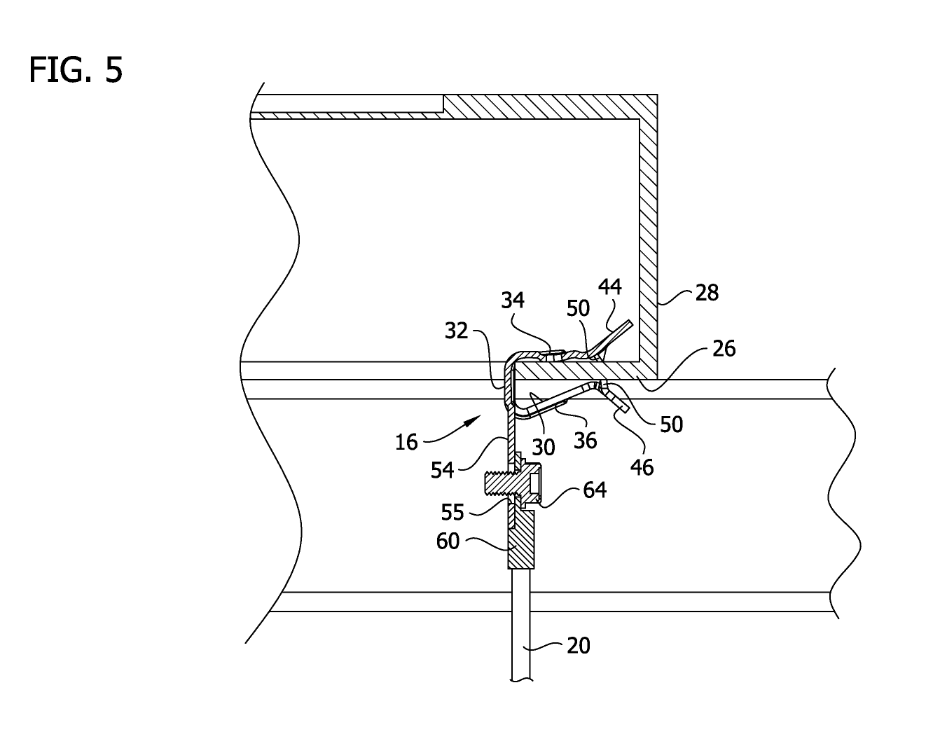

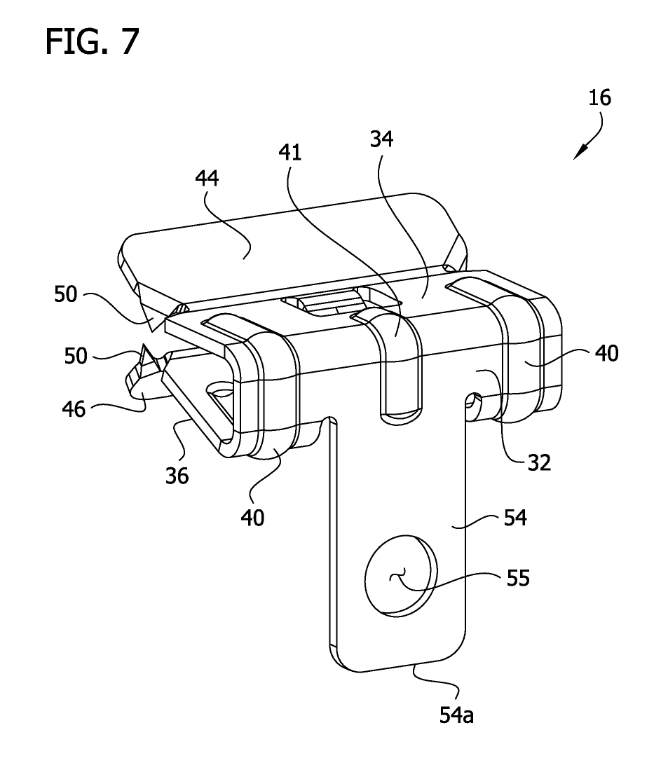

Referring to FIGS. 4 and 5, the module clip 16 is securable to a lower flange 26 of a frame 28 of the photovoltaic module 12. In particular and as shown in FIG. 5, the module clip 16 defines a press-fit channel 30 in which the lower flange 26 of the module frame 28 is press fit to secure the clip to the module. As shown best in FIGS. 5-7 and 9, the illustrated module clip 16 includes a channel base (or loop) 32 and opposing upper and lower clip jaws 34, 36 (broadly, first and second clip jaws), respectively, extending from the channel base to define the press-fit channel 30. It is understood that each of the upper and lower clip jaws 34, 36, as with the illustrated embodiment, may have one or more openings therethrough, whereby the press-fit channel 30 is discontinuous across the module clip 16.

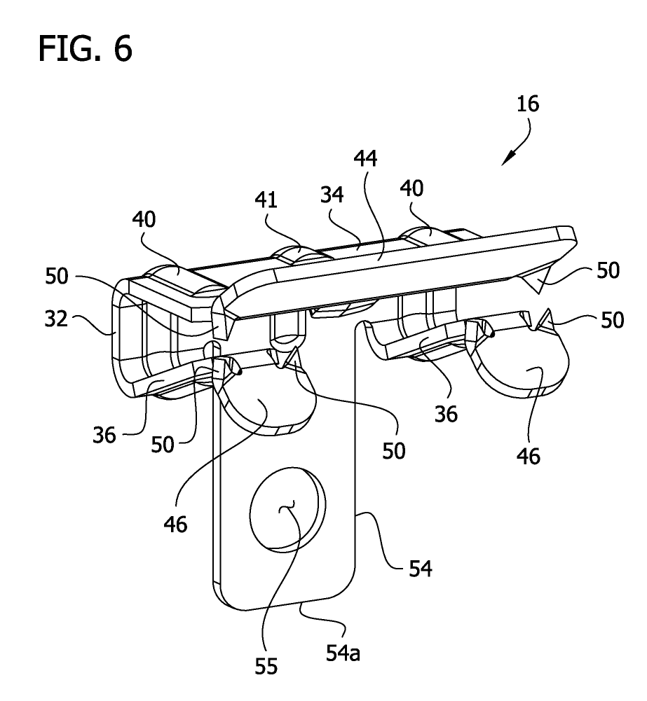

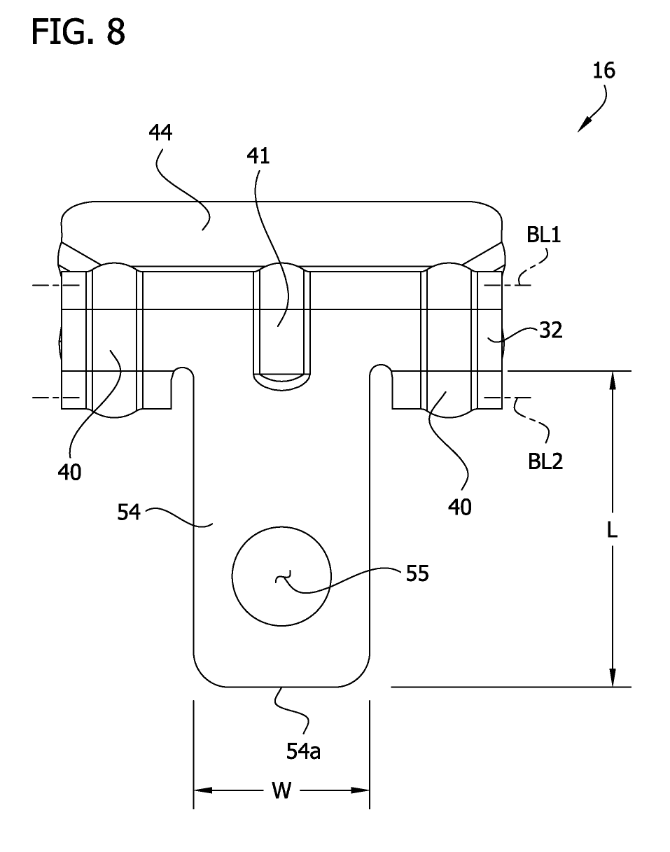

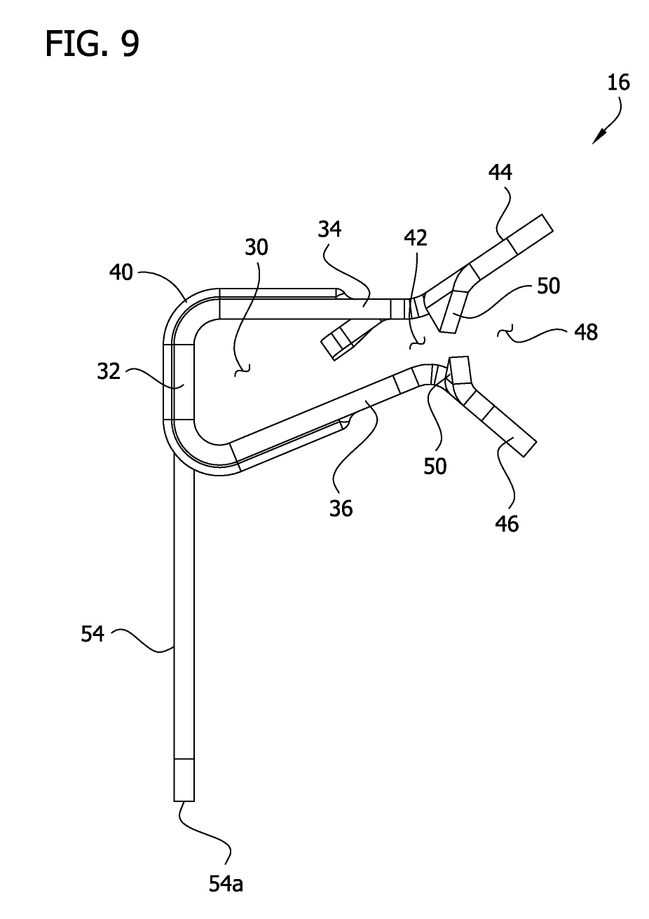

Referring to FIGS. 6-9, the illustrated module clip 16 is a spring clip (or “hammer-on clip,” though a hammer may not necessarily be used), whereby at least one of upper and lower clip jaws 34, 36 is resiliently deflectable away from the other clip jaw as the clip is pressed on the lower flange 26. The illustrated module clip 16 includes ribs 40 extending along the fastener from the upper clip jaw 34 to the lower clip jaw 36, and a central rib 41 extending from the upper clip jaw to the channel base 32, to provide structural rigidity to the clip jaws and inhibit bending, and to increase the spring force exerted by the spring clip. In the illustrated embodiment (shown best in FIGS. 5 and 9), the clip jaws 34, 36 extend toward one another from the channel base 32 such that the channel base and the clip jaws have a generally triangular or tapered profile. Referring to FIG. 9, a throat 42 of the press-fit channel 30 is defined generally at the apex of the triangular or tapered profile (i.e., the location where the clip jaws 34, 36 are the least distance apart from one another). The upper clip jaw 34 is resiliently deflectable about an upper bend line BL1 (FIG. 8) adjacent the juncture of the channel base 32 and the upper clip jaw, and the lower clip jaw 36 is resiliently deflectable about a lower bend line BL2 (FIG. 8) adjacent the juncture between the channel base and the lower clip jaw. When the module clip 16 is secured to the lower flange 26 (as shown in FIG. 5), tension at the bend lines BL1, BL2 urges the clip jaws 34, 36 toward the lower flange 26, thereby squeezing or gripping on to the lower flange to firmly secure the clip to the module 12. Terminal end margins 44, 46 (or lips) of the respective upper and lower clip jaws 34, 36 flare outward, at locations adjacent to the throat 42, to define an enlarged entrance 48 (FIG. 9) of the press-fit channel 30 that facilitates insertion of the lower flange 26 into the press-fit channel. The module clip 16 may be of other configurations without departing from the scope of the present invention.

As set forth above, the module clip 16 is configured to provide an electrical connection between the module 12 and the rail 14 of the racking assembly to facilitate grounding of the module. As is generally known in the art, the module frame 28 is typically constructed from an electrically-conductive material, such as aluminum or another electrically conductive metal, having an electrically non-conductive outer layer disposed over the electrically conductive material. For example, the module frame 28 may be constructed from anodized aluminum, which has an outer anodic layer that is electrically non-conductive. Accordingly, at least one of the upper and lower clip jaws 34, 36 of the module clip 16 includes one or more piercing members 50 that pierce through (e.g., score, scrape, dig, and/or puncture) the anodic layer, or other electrically non-conductive outer layer, and make electrical contact with the electrically conductive material (e.g., aluminum) as the lower flange 26 of the module frame 28 is press-fit in the press-fit channel 30. In the illustrated embodiment, both the upper and lower clip jaws 34, 36 include piercing members 50 (e.g., teeth). The piercing members 50 on the upper clip jaw 34 extending slightly downward from the terminal end margin 44 of the upper clip jaw and into, or generally adjacent to, the throat 42 of the press-fit channel 30. As shown best in FIG. 9, the piercing members 50 on the lower clip jaw 36 extend slightly upward from the terminal end margin 46 of the lower clip jaw and into, or generally adjacent to, the throat 42 of the press-fit channel 30. It is understood that the locations of the piercing members 50 may be other than disclosed. The piercing members 50 may extend at an angle from about 15 degrees to about 45 degrees relative to the respective terminal end margins 44, 46 of the upper and lower clip jaws 34, 36, respectively.

As the module clip 16 is pressed on, hammered on, or otherwise press fit on the lower flange 26, the piercing members 50 engage the lower flange 26 and score or scrap (i.e., puncture) the anodic layer and contact the electrically-conductive material. Further press fitting of the module clip 16 on the lower flange 26 may cause the piercing members 50 to resiliently deflect (i.e., flatten out), whereby the teeth continue to score the anodized layer, while being urged into contact with the electrically-conductive material, to increase the area of contact between the teeth and the electrically-conductive material. In one embodiment, the module clip (i.e., at least one of the upper and lower jaws 34, 36) may be configured to apply a minimum force of about 30 pound-force to about 70 pound-force to the lower flange 26 to facilitate piercing of the lower flange by the piercing members 50.

Referring to FIGS. 6-9, a lead-connecting member 54 (e.g., a tab) extends downward from the channel base 32 generally adjacent the lower clip jaw 36. The lead-connecting member 54 lies generally within the same plane as the channel base 32 (as shown in FIG. 9), generally transverse to the press-fit channel 30. The illustrated lead-connecting member 54 has an opening 55 therein for use in securing the ground wire 20 to the lead-connecting member, as explained in more detail below. Referring to FIG. 8, the lead-connecting member 54 has a substantially uniform width W along its entire length L from the juncture of the lead-connecting member and the channel base 32 to a terminal end 54a of the lead-connecting member. In one example, the width of the lead-connecting member 54 may be at least about 0.500 inches (1.27 cm), the thickness of the lead-connecting member 54, which is substantially uniform along its entire length, may be about 0.044 in, and the length L of the lead-connecting member may be about 1.0 in.

The module clip 16 is electrically conductive so as to define an electrical path from the electrically-conductive material of the module frame 28, through the piercing members 50, the jaws 34, 36, and the lead-connecting member 54, to the ground wire 20. In one example, the module clip 16 is capable of electrically conducting current through the electrical path as required by UL 467 and/or UL2703, to effectively ground the module through the rail 14. In one non-limiting example, the module clip 16 is constructed to have a current-carrying capacity through the electrical path of at least 750 amps for four seconds to satisfy the requirement of UL 467. In another non-limiting example, the module clip 16 may be wired in series with an applicable fuse (e.g., a 60 amp fuse) and connected to a 5,000 amp source. In this example, the module clip 16 has a current-carrying capacity of at least 135% current (e.g., 81 amperes, where the fuse is a 60 am fuse) for sixty minutes and at least 200% current (e.g., 120 amperes, where the fuse is a 60 am fuse) for four minutes. It is understood that the module clip 16 may have other current-carrying capacities without departing from the scope of the present invention. It has been found that for the clip to have a desired current-carrying capacity, such as that of a 10 gauge wire, three features may need to be present for the clip to function as desired. First, the lead-connecting member 54 must be of sufficient cross-sectional area to carry the specified current from at least one of the clip jaws 34, 36 to the ground wire 50 without getting so hot as to fail and no longer have continuity with at least one of the clip jaws 34, 36. Second, the portion of the clip jaws 34, 36 that carry current from the piercing member(s) 50 to the lead-connecting member 54 should have a collective cross-sectional area suitable for collectively carrying the desired current. And third, the piercing member(s) 50 should be configured such that when the clip 16 is pressed onto the frame 26 of the solar module 12, the piercing members “plow” or cut into the frame to a suitable depth such that the collective area of the piercing members in direct contact with the conductive material disposed under the non-conductive layer is sufficient to carry the desired current.

In the illustrated embodiment, the module clip 16 is integrally formed as a unitary, one-piece construction. Thus, the lead-connecting member 54 is formed integrally with the upper and lower jaws 34, 36, respectively, and the channel base 32. For example, the upper and lower jaws, 34, 36, respectively, the channel base 32, and the lead-connecting member 54 may be fabricated from a single sheet of metal, such as spring steel. In such an embodiment, the single sheet of metal may be bent to form the upper and lower clip jaws 34, 36, respectively, and the sheet may be lanced to form the piercing members 50 and the lead-connecting member 54. In one embodiment, the piercing members 50 may have a hardness from about 46 Rockwell C scale to about 50 Rockwell C scale to facilitate piercing of the lower flange 26. In one example, the module clip 16 may be formed from a sheet of metal (e.g., spring steel) having a thickness from about 18 gauge to about 20 gauge or from about 0.035 in to about 0.048 in, and in one example, about 16 gauge or from about 0.053 in to about 0.065 in. Other ways of making the module clip 16 do not depart from the scope of the present invention.

In the illustrated embodiment, where the lead-connecting member 54 is formed integrally with the upper and lower jaws 34, 36, respectively, and the channel base 32, the lead-connecting member 54 has a substantially uniform width W along substantially its entire length L from the juncture of the lead-connecting member and the channel base 32 to the terminal end 54a of the lead-connecting member. The lead-connecting member 54 has a substantially uniform width along substantially its entire length L to avoid a region of weakness in the lead-connecting member 54 where the chance of failure (e.g., melting), due to the amount of current flowing through the module clip, is reduced. It has been found, through testing, that a device including a lead-connecting member having a necked-down portion with a width of 0.35 in and a thickness of 0.044 in (i.e., a cross-sectional area of 0.0154 in²) at the juncture of the lead-connecting member and the channel base 32 is not suitable for directing an electrical current of 750 amps for 4 seconds (instead, it was capable of directing an electrical current of 400 amps for 4 seconds). However, a module clip constructed from the same sheet metal with the same thickness of 0.044 in and including a lead-connecting member having a width of 0.50 in (i.e., a cross-sectional area of 0.022 in²) along substantially its entire length is suitable for directing an electrical current of 750 amps for 4 seconds. As can be seen from this testing, the cross-sectional area of the necked-down portion of the first device was not sufficient to carry the desired capacity, while the cross-sectional area of the lead-connecting member of the second device, which was constructed according to the teachings of the present disclosure, was sufficient to carry the desired capacity. The second device was also found to carry 5000 amps for a sufficient amount of time to allow a 60 amp fuse to short the circuit.

Referring to FIGS. 2-4, the illustrated rail-attachment component 18 comprises a strut channel clip (also indicated by reference numeral 18) that is configured to snap onto a lip of the strut channel rail 22. The strut channel clip 18 makes good electrical contact with the electrically conductive material of the strut channel rail 22. The rail-attachment component 18 has an opening 59 for attaching the ground wire 20 to the rail-attachment component, as explained in more detail below. A suitable rail-attachment component 18 for use in the ground lead assembly 10 is the BSC4 Strut Clip sold by Cooper B-Line of Highland, Ill. The rail-attachment component 18 may be of other configurations without departing from the scope of the present invention. For example, the rail-attachment component may be one of several types of fasteners suitable for securing the ground wire 20 to the illustrated rail 14 or another type rail.

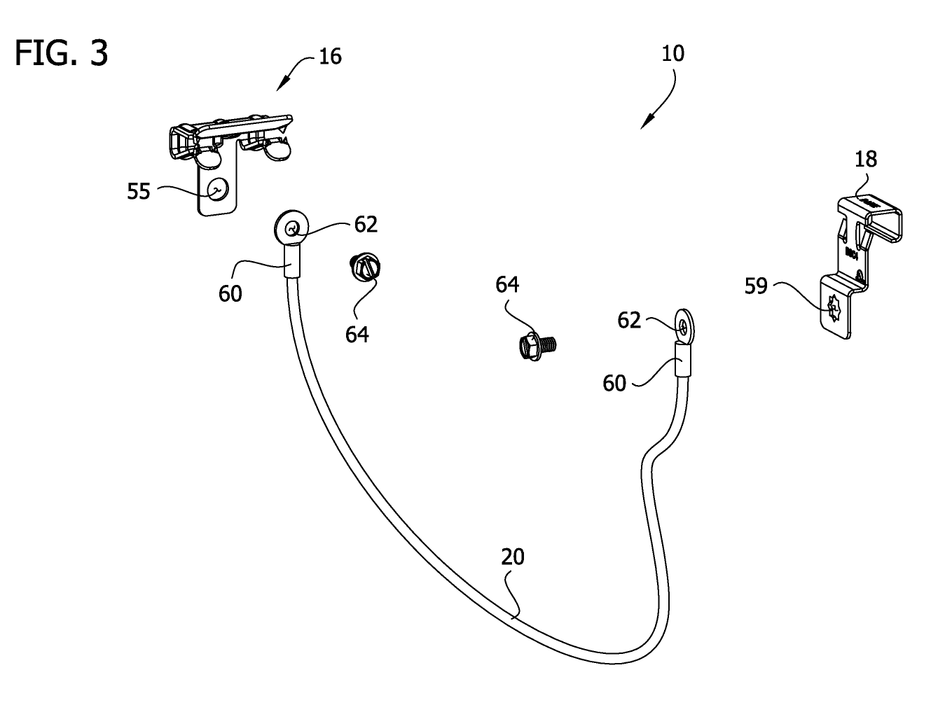

Referring to FIG. 3, the ground wire 20 includes wire connectors 60 (e.g., ring connectors, as illustrated) at opposite ends of the ground wire for securing and electrically connecting the ground wire to the module clip 16 and the rail-attachment component 18. To secure the wire connectors 60 to the module clip 16 and the rail-attachment component 18, openings 62 in the wire connectors are aligned with the respective openings 55, 59 in the module clip 16 and the rail-attachment component 18, and fasteners 64 (e.g., bolts) are threaded through the aligned openings. The ground wire 20 may be securable to the module clip 16 and the rail-attachment component 18 in other ways, such as soldering. In one embodiment, the ground wire 20 may be a 10 gauge copper wire, although it may be of another size and/or material without departing from the scope of the present invention.

In one embodiment, each of the modules 12 of the photovoltaic system is grounded through one of the rails 14 of the racking assembly using one or more ground lead assemblies 10. The module 12 is quickly and easily grounded through one of the rails 14 by press fitting the module clip 16 onto the lower flange 26 of the module, such as by using a hammer or other tool, whereby the piercing members 50 of the module clip pierce through (e.g., score, scrape, dig, and/or puncture) the anodic layer—or other electrically non-conductive outer layer—of the flange 26, and make electrical contact with the electrically conductive material (e.g., aluminum). The rail-attachment component 18 is connected to the rail 14 by snapping the rail-attachment component onto one of the lips of the rail.

Having described embodiments of the invention in detail, it will be apparent that modifications and variations are possible without departing from the scope of the invention defined in the appended claims.

When introducing elements of the present invention or the preferred embodiments(s) thereof, the articles “a”, “an”, “the” and “said” are intended to mean that there are one or more of the elements. The terms “comprising”, “including” and “having” are intended to be inclusive and mean that there may be additional elements other than the listed elements.\

As various changes could be made in the above constructions, products, and methods without departing from the scope of the invention, it is intended that all matter contained in the above description and shown in the accompanying drawings shall be interpreted as illustrative and not in a limiting sense.

What is claimed is:

1. A ground lead assembly for use in grounding a photovoltaic module through electrical connection with a racking assembly on which the photovoltaic module is mountable, the ground lead assembly comprising:
a module clip configured for securement to the photovoltaic module, the module clip including upper and lower clip jaws at least partially defining a press-fit channel for press fitting the module clip onto a lower flange of the photovoltaic module, and a piercing member on at least one of the upper and lower clip jaws for piercing an electrically non-conductive outer layer on the lower flange of the photovoltaic module and contacting an electrically conductive material of the lower flange as the module clip is press fit onto the lower flange; and
a rail-attachment component connected electrically to the module clip, the rail-attachment component configured for securement to and electrical connection with a rail of the racking system.

2. The ground lead assembly set forth in claim 1, wherein at least one of the upper and lower clip jaws is resiliently deflectable generally away from the other of the upper and lower clip jaws to facilitate press-fitting of the module clip onto the lower flange of the photovoltaic module and to facilitate piercing of the electrically non-conductive outer layer.

3. The ground lead assembly set forth in claim 2, wherein the module clip includes a lead-connecting member configured for securement to a ground wire to electrically connect the ground wire to the module clip.

4. The ground lead assembly set forth in claim 3, wherein the module clip includes a channel base from which the upper and lower clip jaws extend, the lead-connecting member extending downward from the channel base adjacent the lower clip jaw.

5. The ground lead assembly set forth in claim 4, wherein the lead-connecting member has length extending from the channel base to a terminal end of the lead-connecting member, the lead-connecting member having a cross-sectional area that is substantially uniform along substantially an entirety of the length of the lead-connecting member.

6. The ground lead assembly set forth in claim 5, wherein the lead-connecting member has an opening for use in securing the ground wire to the lead-connecting member.

7. The ground lead assembly set forth in claim 1, further comprising a ground wire secured to the module clip and the rail-attachment component, wherein the ground wire electrically connects the module clip to the rail-attachment component.

8. The ground lead assembly set forth in claim 7, wherein the rail-attachment component comprises a strut-channel clip configured to clip onto the rail.

9. The ground lead assembly set forth in claim 8, wherein the strut-channel clip has an opening therein for use in securing the ground wire to the strut-channel clip.

10. A module clip for use in grounding a photovoltaic module through electrical connection with a racking assembly on which the photovoltaic module is mountable, the module clip comprising:
upper and lower clip jaws at least partially defining a press-fit channel for press fitting the module clip onto a lower flange of the photovoltaic module;
a piercing member on at least one of the upper and lower clip jaws for piercing an electrically non-conductive outer layer on the lower flange of the photovoltaic module and contacting an electrically conductive material of the lower flange as the module clip is press fit onto the lower flange; and
a lead-connecting member for use in securing a ground wire to the module clip,
wherein the piercing member is electrically connected to the lead-connecting member so as to define an electrical path from the piercing member to the lead-connecting member, the module clip having a current-carrying capacity through said electrical path of at least about 750 amps for 4 seconds.

11. The module clip set forth in claim 10, wherein the lead-connecting member has a length extending outward from adjacent the lower clip jaw to a terminal end of the lead-connecting member, the lead-connecting member having width that is substantially uniform along substantially an entirety of the length of the lead-connecting member.

12. The module clip set forth in claim 11, wherein the width of the lead-connecting member is at least about 0.500 inches (1.27 cm).

13. The module clip set forth in claim 12, wherein the module clip is formed from a single sheet of metal having a thickness of at least 0.044 in.

14. A photovoltaic system comprising:
a racking assembly including a rail;
a photovoltaic module mounted on the rail of the racking assembly, the photovoltaic module including a frame having a lower flange, wherein the frame is constructed from an electrically-conductive material having an electrically non-conductive outer layer disposed over the electrically conductive material;
a ground lead assembly grounding the at least one photovoltaic module through electrical connection with the rail on which the photovoltaic module is mounted, the ground lead assembly including
a module clip press fit on the lower flange of the photovoltaic module, the module clip having a piercing member electrically contacting the electrically conductive material, and
a rail-attachment component secured to the rail in electrical connection therewith, wherein the rail-attachment component is electrically connected to the module clip to provide an electrical path from the electrically conductive material of the photovoltaic module through the ground lead assembly to the rail.

15. The photovoltaic system set forth in claim 14, wherein the ground lead assembly further comprises a ground wire secured to the module clip and the rail-attachment component for electrically connecting the module clip to the rail-attachment component.

16. The photovoltaic system set forth in claim 15, wherein the rail is a strut channel and the rail-attachment component is a strut-channel clip.

17. The photovoltaic system set forth in claim 16, wherein the ground lead assembly has a current-carrying capacity of at least 750 amps for four seconds.
